(19) United States
(12) Patent Application Publication
(10) Pub. No.: US 2017/0288140 A1
(43) Pub. Date: Oct. 5, 2017

(54) 1S1R MEMORY CELLS INCORPORATING A BARRIER LAYER

(71) Applicant: Intel Corporation

(72) Inventors: Elijah V. KARPOV, Portland, OR (US); Niloy MUKHERJEE, Portland, OR (US); Prashant MAJHI, San Jose, CA (US); Robert S. CHAU, Beaverton, OR (US)

(21) Appl. No.: 15/505,909

(22) PCT Filed: Sep. 25, 2014
(86) PCT No.: PCT/US14/57494

§ 371 Date: Feb. 22, 2017

(51) Int. Cl. H01L 45/00; H01L 27/24

(52) U.S. Cl. CPC H01L 45/146; H01L 45/147; H01L 45/1233; H01L 45/142; H01L 45/14; H01L 27/2436; H01L 45/16

(57) ABSTRACT

Thin film 1S1R bitcells incorporating a barrier between selector and memory elements. Devices incorporating such bitcells and methods of forming such bitcells are also described. In embodiments, the selector and memory element is each a dielectric material, and advantageously a metal oxide. Between the selector and memory elements is a barrier, which is to reduce intermixing and/or reaction of selector material and memory material. Addition of a barrier layer having suitable material properties into the 1S1R stack may extend the operating lifetime of a bitcell incorporated the stack by resisting intermixing and/or reaction of the selector and memory thin film materials driven by thermal and/or electric field stresses experienced by a bitcell during operation. In embodiments, a barrier layer may include one or more material layers having a composition distinct from the material composition(s) of the selector and memory elements.

### BACKGROUND

Nonvolatile memory (NVM) is a form of memory widely utilized in the microelectronics industry. To date, the dominant form of NVM has been flash (e.g., NAND, NOR, etc.). However, many alternative NVM technologies are under development for next generation devices. One of the considerations for next-gen NVM technology is how readily it can be integrated with CMOS logic circuitry. Embedded non-volatile memory (e-NVM) is a non-volatile memory integrated on-chip with logic devices (e.g., fabricated in CMOS technology). e-NVM is therefore distinct from stand-alone NVM where the memory array is fabricated on a substrate dedicated to the memory. Embedded NVM advantageously eliminates the need for inter-chip communication between a processor and off-chip memory, and consequently enables high-speed data access and wide bus-width capability to any logic implemented on-chip along with the e-NVM (e.g., cores of a CPU, graphics processor execution unit, etc.).

Of the various NVM technologies, resistive memory technologies continue to show significant promise both for discrete and e-NVM applications. In a resistive memory, such as resistive random-access memory (ReRAM or RRAM), the bitcell generally includes a two-terminal device in which a comparatively insulating memory material that is switchable is disposed between two relatively more conductive electrodes. Within the bitcell the memory material can switch between two different states: a high-resistance state (HRS), which may be representative of an off or 0 state; and a low-resistance state (LRS), which may be representative of an on or 1 state. Typically, a reset process is used to switch the ReRAM device to the HRS using a reset voltage, and a set process is used to switch the ReRAM device to the LRS using a set voltage.

One of the important metrics for resistive memory technology is the programming voltage. Because of the limited operating voltage found in state of the art CMOS (e.g., V_{cc}<0.9V), achieving a sufficiently low programming voltage is particularly challenging for e-NVM applications.

Many ReRAM device architectures directed toward low programming voltages have been plagued with high sneak path leakage. If bitcell off-state leakage is too high, a large cross-bar array may consume too much power. Some hybrid ReRAM bitcell architectures further incorporate a thin film selector element (1S) along with a resistive memory element (1R) to reduce off-state leakage at some cost of programming voltage overhead associated with the selector element. Such “1R1S” bitcell architectures may be implemented with any of the many selector element technologies integrated monolithically with any of the many memory element technologies.

Another of the important metrics for resistive memory technology is bitcell reliability. Reliability is generally characterized with a number of set/reset cycles. For commercial applications, a bitcell may need to display stability over a million cycles, or more.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a circuit schematic of a thin film 1S1R bitcell incorporating a barrier between selector and memory elements, in accordance with an embodiment;

FIG. 1B is a graph illustrating I-V response of a thin film 1S1R bitcell incorporating a barrier between selector and memory elements, in accordance with an embodiment;

FIG. 2A is a cross-sectional view of a thin film 1S1R bitcell incorporating a bulk conductive oxide barrier material between a selector dielectric material and memory oxide material, in accordance with an embodiment;

FIG. 2B is a cross-sectional view of a thin film 1S1R bitcell incorporating non-oxide metallic compound between a selector dielectric material and memory oxide material, in accordance with an embodiment;

FIGS. 3A and 3B are cross-sectional views of a thin film 1S1R bitcell incorporating a multi-layered barrier between a selector dielectric material and memory oxide material, in accordance with embodiments;

FIG. 4 is a cross-sectional view illustrating a non-planar thin film 1S1R bitcell incorporating a conductive oxide barrier between a selector dielectric material and memory oxide material, in accordance with embodiments;

FIG. 5 is a cross-sectional view illustrating stacked thin film 1S1R bitcells, in accordance with embodiments;

FIG. 6 is a flow diagram illustrating a method of forming a thin film 1S1R bitcell incorporating a barrier between a selector oxide material and memory oxide material, in accordance with embodiments;

FIG. 7 is a flow diagram illustrating a method of forming a thin film 1S1R bitcell incorporating a multi-layered barrier between a selector oxide material and memory oxide material, in accordance with embodiments;

FIG. 8 is a schematic of a NVM including a plurality of thin film 1S1R bitcells incorporating a barrier between selector and memory elements, in accordance with embodiments;

FIG. 9 illustrates a cross-section of e-NVM, in accordance with embodiments;

FIG. 10 illustrates a mobile computing platform and a data server machine employing an SoC having e-NVM with 1S1R bitcells incorporating a barrier between selector and memory elements, in accordance with embodiments of the present invention; and

FIG. 11 is a functional block diagram of an electronic computing device, in accordance with an embodiment of the present invention.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used in the description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Described herein are thin film 1S1R bitcells incorporating a barrier between selector and memory elements. Devices incorporating such bitcells and methods of forming such bitcells are also described. In embodiments, the selector and memory element is each a dielectric material, and is advantageously an oxide. Between the selector and memory elements is a barrier, which is to reduce selector material and memory material intermixing and/or reaction. Whereas the thermal and/or electric field stresses experienced by a bitcell during operation serve to drive intermixing and/or reaction of the selector and memory thin film materials in a manner that may limit reliability of a 1S1R stack, it has been found that the addition of a barrier layer having suitable material properties into the 1S1R stack can significantly extend the operating lifetime of the bitcell. NVM devices in accordance with embodiments exemplified herein may therefore have advantageously high endurance (e.g., set/reset cycle counts). As further described below, a barrier layer may include one or more material layers having a material composition distinct from the material composition(s) of the selector and memory elements. As also described below, exemplary 1S1R stacks described herein may be readily adapted to various planar and non-planar NVM and e-NVM architectures.

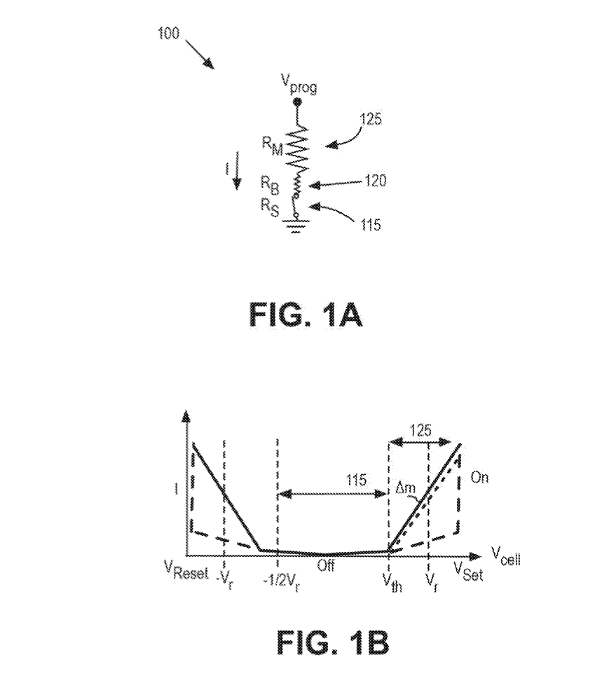

FIG. 1A is a circuit schematic of a thin film 1S1R bitcell 100 incorporating a barrier 120 between a selector element 125 and a memory element 115, in accordance with an embodiment. Thin film selector element 125, thin film memory element 115, and thin film barrier 120 in electrical series. A pair of electrodes is coupled to opposite ends of bitcell 100 while barrier 120 electrically floats (i.e., is not tied to either ground or V_{cell}). Memory element 115 is switchable between a high resistance state and a low resistance state to store one of a “1” or “0” associated with the bi-stable bitcell states. Selector element 125 is to allow access to memory element 115 in a manner that reduces sneak path leakage within an array including a plurality of bitcell 100. Selector element 125 therefore shares some of the functions of an access transistor, but is significantly more scalable. FIG. 1B is a graph illustrating I-V response of thin film 1S1R bitcell 100, in accordance with an embodiment. As shown, 1S1R bitcell 100 is bidirectional. Selector element 125 is associated with a threshold voltage Vₜₕ, below which bitcell current I is at some nominal leakage level while in an “OFF” state. Above threshold voltage Vₜₕ, selector element 125 in the “ON” state passes some threshold current I, which increases substantially linearly to enable reading of state for memory element 115 at read voltage Vᵣ, and a transition of state (e.g., set/reset) for memory element 115 at higher voltage magnitudes.

In embodiments, memory element 115 includes a memory oxide material, which is advantageously an amorphous material that may be conductive in bulk or thin film form, and/or capable of undergoing an insulator-metal transition (e.g., Mott transition, charge induced transition, or the like). For conductive oxide embodiments where the material is conductive in bulk or thin film form, resistance nevertheless varies significantly between the LRS and HRS. In further embodiments, selector element 125 includes a selector oxide material, which advantageously is to undergo an insulator-metal transition. Alternatively, non-oxide selector element embodiments are chalcogenide-based. Some of these non-oxide dielectric materials, such as CuTe, display similar IV switching characteristics, although they may lack the pronounced step increase I vs. V in forced voltage IV sweeps displayed by advantageous selector oxide materials.

Barrier 120 may be incorporated into a wide array of thin film resistive memory architectures in which any known selector element material may be incorporated with any known memory element material to form a thin film 1S1R stack. Such a barrier is useful where two active (switchable) materials are in close proximity, exposed to nearly identical operating environments, and the action of one switchable element may impact the action of the other switchable element detrimentally over time or set/reset cycles. Barriers in accordance with embodiments are advantageous where the memory element is an oxide material, with the barrier being particularly advantageous where memory and selector elements are both thin film oxide materials having distinct compositions. For such embodiments, the inventors understand the oxide thin films to be especially susceptible to intermixing from enhanced solid state diffusion driven by localized Joule heating, and/or from species drift driven by high peak fields, associated with oxide-based 1S1R systems.

Intermixing may be detrimental to the stability of the oxide-based 1S1R stack either because the distinct functionality of one or both materials is gradually lost, or because latent formation of a parasitic intermixed layer incurs greater voltage drop over time rendering the available working voltage insufficient for the 1S1R stack to function. Physical contact between selector and memory materials poses even more of a concern where species in a first material (e.g., memory oxide) is susceptible to chemical reaction with species in a second material (e.g., selector oxide). As valencies and ionic character may vary between the memory oxide and the selector dielectric, activation energy provided during device operation may drive the materials interface into states of greater stability. Hence, while a barrier incurs some bitcell operational overhead associated with any additional electrical resistance attributable to the barrier, and some bitcell fabrication overhead associated with additional thin film stack complexity attributable to the barrier, a barrier having a particular microstructure, thickness, and/or composition can provide significant improvements in the oxide-based 1S1R memory cell endurance. In certain embodiments, a barrier layer may increase 1S1R cell endurance by at least two, and advantageously three, orders of magnitude.

In exemplary embodiments, barrier 120 is of one or more thin film material that maintains a substantially constant and bi-directional electrical resistance over an operating voltage sweep of bitcell 100 (i.e., barrier 120 is passive, non-switchable, non-rectifying). As illustrated in FIG. 1B, resistance of the 1S1R stack including barrier 120 increases nominally by Am relative to a 1S1R stack including only memory element 115 directly connected in series to selector element 125. In advantageous embodiments, the resistance contribution of barrier 120 is small, for example less than that of the series summed resistance of memory element 115 and selector element 125 at V_{read}. A small barrier resistance R_{B} advantageously reduces the voltage dropped across the barrier, retaining supply voltage for the active portions of bitcell 100. In one advantageous embodiment, barrier 120 has a resistance R_{B} to current I that is less than resistance R_{M} associated with memory element 115 when memory element 115 is in a linear, conductive state. In further embodiments, R_{B} is less than 30% of R_{M}, and ideally less than 20%. Resistance R_{B} is a function of both barrier thin film thickness and barrier resistivity. Exemplary barrier embodiments have a material resistivity in the range of 0.1 mOhm cm to 10 Ohm cm when measured at low field.

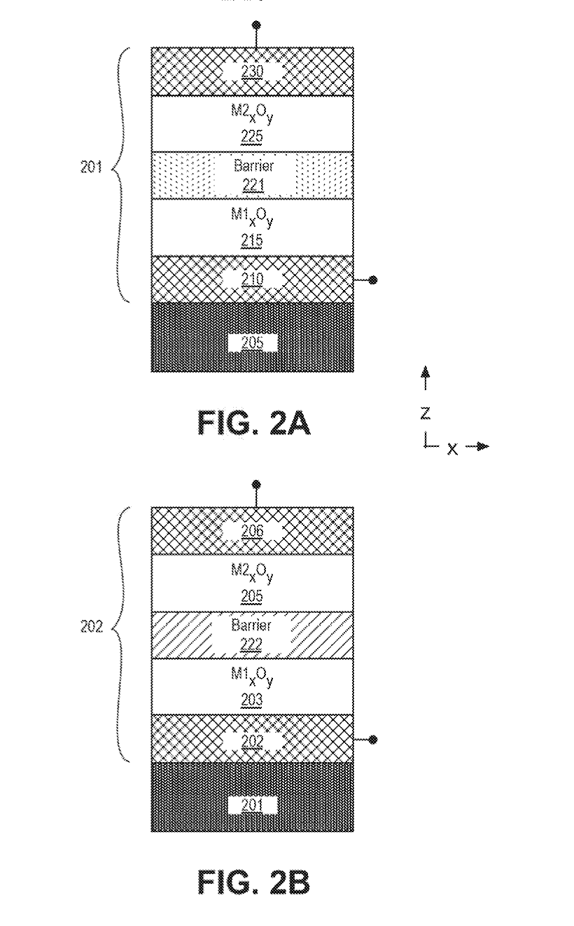

In further embodiments, barrier 120 is also a good solid state diffusion barrier. To this end, barrier 120 is ideally amorphous, but if not, grain structure of barrier 120 is advantageously non-columnar through the thickness of barrier 120 to better resist intermixing of adjacent materials. A barrier film's ability to resist intermixing generally increases with thickness. However, because of the advantage of low barrier electrical resistance, a barrier cannot be arbitrarily thick. In exemplary embodiments, the barrier has a film thickness (e.g., z-height in FIG. 2A) in the range of 2-20 nm, or more, as permitted by the resistivity of the particular barrier, the bitcell supply voltage budget, and the set/reset voltage required by the memory element. In one advantageous embodiment, where the supply voltage is no more than 1V, the barrier is less than 20 nm.

In embodiments, a thin film 1S1R bitcell barrier includes at least one of a bulk conductive metal oxide, or a non-oxide metallic compound. FIG. 2A is a cross-sectional view of a thin film 1S1R bitcell 201 disposed over a substrate 205. Bitcell 201 incorporates a bulk conductive oxide barrier material 221 between a memory oxide material 215 and a selector dielectric material 225. FIG. 2B is a cross-sectional view of a thin film 1S1R bitcell 202 incorporating a metal nitride, carbide, or carbonitride barrier material 222 between memory oxide material 215 and selector dielectric material 225, in accordance with an alternate embodiment.

Referring first to FIG. 2A, bitcell 201 is disposed over a substrate 205 that may be any substrate known to be suitable for supporting a thin film 1S1R bitcell, such as, but not limited to: crystalline semiconductor materials, including, but not limited to, silicon, germanium, and SiGe, etc.; and amorphous materials including glasses, organic polymers, and plastics, etc. In further embodiments, substrate 205 represents a back end of line (BEOL) layer. For example bitcell 201 may be formed on or above an underlying semiconductor device layer of an integrated circuit (IC). As such, substrate 205 may also include thin film laminates (e.g., metals, dielectrics, etc.) commonly found in IC industry.

Disposed over substrate 205 are a pair of first and second electrodes 210, 230, which may be of a same or different composition and may further include one or more thin film layers, as further described below. A thin film memory oxide (e.g., M1ₓO_{y}) material 215 is disposed proximal electrode 210. In the illustrated embodiment, memory oxide material 215 is disposed in direct contact with electrode 210. Memory oxide material 215 is an oxide material that can change resistance values between high and low resistance states in a non-volatile fashion when opposite polarity voltages are applied. In some embodiments the oxide can undergo reversible metal-insulator transition. In some embodiments the oxide material is conductive in bulk and/or thin film form. In one exemplary embodiment, the memory oxide material 215 is a transition metal oxide including stoichiometric and sub-stoichiometric ionic oxides AOₓ, where A is a transition metal. In certain such embodiments, the oxide memory element material is an anionic-based oxide material. Non-limiting examples of anionic-based oxides include, but are not limited, to oxides of V (e.g., V₂O₅), Nb (e.g., Nb₂O₅), or Cr (e.g., Cr₂O₃), Ta (e.g. Ta₂O₅), Hf (e.g. HfO₂) as well as ternary, quaternary alloys such as SnO₂-doped Indium oxide, as well as oxide alloys with metals from the adjacent columns of periodic table (e.g., Y, Zr in Y₂O₃ -doped ZrO₂ and Sr and La in La₁₋ₓSrₓGa_{1-y}Mg_{y}O₃). The anionic-based oxides may also be non-stoichiometric oxides of these same elements and their alloys. In other such embodiments, the oxide memory element material is a cationic-based oxide material, examples of which may include but are not limited to LiMnO₂, Li₄TiO₁₂, LiNiO₂, and LiNbO₃.

Memory oxide material 225 may have a film thickness that varies considerably as a function of composition, read, set/reset voltage requirements, etc. In exemplary memory oxide embodiments, such as those employing any of the metal oxide materials described above, the memory oxide material has a thin film thickness of at least 2 nm and advantageously no more than 10 nm.

Proximal to electrode 230 is a thin film selector dielectric (e.g., M2ₓO_{y}) material 225. In the illustrated embodiment, selector dielectric material 225 is disposed in direct contact with electrode 210. In an exemplary embodiment selector dielectric material 225 is an oxide material that is to undergo a volatile insulator-metal transition that switches resistance to low value when a sufficient bias is applied and reverts back to high resistance state when the bias is removed. Like the memory oxide material, a selector oxide material can be a transition metal oxide. Non-limiting examples of selector oxide material include VO₂, NbO₂, Ta₂O₅, Ti₃O₅, Ti₂O₃, and certain mixed oxides, such as LaCoO₃ and SmNiO₃. In certain embodiments, selector dielectric material 225 has an oxide composition distinct from the oxide composition of the memory oxide material 215. In some such embodiments, the selector oxide and memory oxide materials include the same metal species, but at different oxidation states (e.g., NbO₂ selector oxide/Nb₂O₅ memory oxide, Ti₃O₅ selector oxide/TiO₂ memory oxide, etc.). Alternatively, non-oxide selector embodiments, for example based on a chalcogenide, are also possible.

Selector dielectric material 225 may have a film thickness that varies considerably as a function of composition (e.g., oxide vs. chalcogenide), leakage, and threshold current limits, threshold voltage requirements, etc. Generally, greater film thicknesses will have lower leakage, and so in some embodiments selector dielectric material 225 may be thicker than memory oxide material 215. In exemplary selector oxide embodiments, such as those employing any of the metal oxide materials described above, the selector oxide material has a thin film thickness of at least 2 nm and no more than 50 nm.

Disposed between memory oxide material 215 and selector dielectric material 225 is bulk conductive oxide barrier material 221. As noted above, a conductive oxide barrier material 221 is of a material that is relatively conductive in a bulk, non-thin film, state and is an electrically passive series element within bitcell 201. Suitable materials are oxide materials that do not undergo insulator-metal transitions, at least within the operating range of resistive memory bitcell 201. In the exemplary embodiment, conductive oxide barrier material 221 is a rutile-type transition metal dioxides. Non-limiting examples of such a conductive oxide suitable for barrier 221 include: RuO₂, CrO₂, WO₂, IrO₂, PtO₂, MoO₂, or RhO₂. Other options are also possible however, such as ternary alloys, including but not limited to indium tin oxide (i.e., ITO). The exemplary conductive oxides have the advantage of being relatively stable when subjected to the electric field and thermal cycling typical of a 1S1R device. The exemplary conductive oxides may also have good diffusion barrier properties (e.g., amorphous, non-reactive), and therefore reduce the rate of intermixing between the adjacent memory oxide 215 and selector dielectric 225. The exemplary conductive oxides also have reasonably low resistivity values, enabling bitcell 201 to be operable at low voltages (e.g., <1V).

Conductive oxide barrier material 221 may have a film thickness that varies considerably as a function the chosen composition's resistivity and the limit on voltage drop that can be tolerated by bitcell 201 in a given application (e.g., discrete NVM vs. e-NVM). Generally, a greater conductive oxide barrier film thickness will provide a better diffusion barrier. In exemplary conductive oxide barrier embodiments, such as those employing any of the conductive oxide materials described above, the conductive oxide barrier material has a thin film thickness of at least 2 nm, less than 50 nm, and advantageously not more than 20 nm.

Referring next to FIG. 2B, bitcell 202 is again disposed over a substrate 205 and is a thin film stack of memory oxide 215 and selector dielectric 225 disposed between two electrodes 210, 230. Memory oxide 215 and selector dielectric 225 may each be any of the materials described above. In the exemplary embodiment illustrated in FIG. 2B however, a metal nitride, carbide, or carbonitride barrier material 222 physically separates memory oxide 215 and selector oxide 225. This barrier material is advantageously a compound of a transition metal, and more advantageously a refractory metal. Just as for the conductive oxide barrier embodiments described above, the non-oxide transition metal compounds suitable for a barrier maintain metallic character for low resistivity, yet are also good diffusion barriers. Non-limiting examples of suitable non-oxide transition metal compounds include: refractory metal nitrides, such as TiN, TaN, and WN; refractory metal carbides, such as TiC, TaC, WC; and refractory metal carbonitrides, such as TaCN.

Barrier material 222 may have a film thickness that varies considerably as a function the chosen composition's resistivity and the limit on voltage drop that can be tolerated by bitcell 201 in a given application (e.g., discrete NVM vs. e-NVM). Generally, a greater barrier film thickness will have slightly higher resistance, but also better serve as a diffusion barrier. In exemplary embodiments, such as those employing any of the refractory metal compounds described above, the refractory metal nitride/carbide/carbonitride barrier material has a thin film thickness of at least 2 nm, less than 50 nm, and advantageously not more than 20 nm.

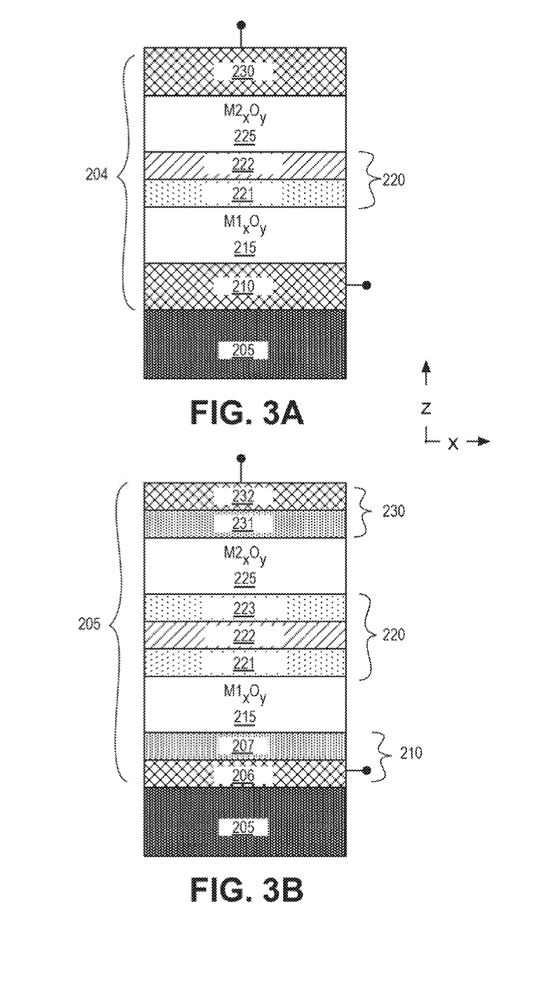

Noting the functional constraints on a barrier (e.g., both low electrical resistance and high intermixing resistance), certain barrier embodiments may employ a plurality of thin films in the form of a multi-layered laminate, or stack. In such embodiments, one or more of the conductive oxide barrier materials described above are laminated with one or more of the conductive non-oxide transition metal barrier materials described above. FIGS. 3A and 3B are cross-sectional views of a thin film 1S1R bitcell 204, 205, each incorporating a multi-layered barrier 220 between memory oxide material 215 and selector dielectric material 225, in accordance with embodiments. For such multi-layered embodiments, the objective is to combine the benefits of the two distinct barrier materials without increasing the resistance of the barrier much beyond that of a single layer barrier. The stability of a conductive oxide barrier material for example may be further enhanced by the diffusion barrier properties, and low resistivity, of the refractory metal nitride/carbide/carbonitride barrier material. Microstructure of a multi-layered barrier may also have advantages over a single-layered barrier. For example, an amorphous conductive oxide material may serve to disrupt a columnar microstructure of a refractory metal nitride/carbide/carbonitride barrier material.

As shown in FIG. 3A, multi-layered barrier 220 includes non-oxide metallic compound barrier material layer 222 disposed directly on (in contact with) conductive oxide barrier material 221. In other embodiments, a conductive oxide barrier material may be disposed directly on a metal nitride, carbide, or carbonitride material. For such bi-layer embodiments, it may be advantageous from a manufacturing standpoint for the conductive oxide barrier material to be disposed on the bottom one of the selector material or memory material, as illustrated in FIG. 3A. In embodiments where one of the selector and memory films is significantly thinner than the other, it may be advantageous from a reliability standpoint for the conductive oxide barrier material to be disposed between the non-oxide barrier material and the thinner selector/memory material.

As shown in FIG. 3B, multi-layered barrier 220 includes metallic, non-oxide barrier material layer 222 disposed directly between (in contact with) two conductive oxide barrier material layers 221, and 223. For such embodiments, conductive oxide barrier material layer 223 may be any of the materials described above for conductive oxide barrier material layer 221. In advantageous embodiments conductive oxide barrier material layer 223 has the same composition as conductive oxide barrier material layer 221, although the compositions may be distinct. Multi-layered barrier material 220 may have a total thin film thickness that varies considerably as a function the various layer composition and number of layers. In exemplary embodiments, either of the bi-layer and tri-layer embodiments illustrated in FIGS. 3A and 3B may have a thin film thickness of at least 2 nm, less than 50 nm, and advantageously not more than 20 nm.

In further reference to the bitcells illustrated in FIGS. 2A, 2B, 3A, and 3B, electrode 210 may be any number of material layers, each layer incorporating one or more of carbon, gold, nickel, platinum, palladium, vanadium, chromium, iridium, tantalum, tantalum nitride, tantalum carbide, manganese, zirconium, hafnium, titanium, titanium nitride, titanium carbide, tungsten, tungsten carbide, tungsten nitride, and alloys thereof. Electrode 230 may also be of any of these materials, although in some embodiments electrodes 210 and 230 do not have the same composition. For example, the electrode proximal to the memory oxide (e.g., electrode 210) may be titanium (or compound thereof) while the electrode proximal to the selector dielectric (e.g., electrode 230) is another material such as W (or compound thereof). In further embodiments, at least one electrode comprises a multi-layered electrode stack, for example including an electrode bulk material of sufficiently low resistance (e.g., copper) and an electrode barrier material between the bulk electrode material and memory/selector material.

FIG. 3B illustrates a multi-layered electrode, in accordance with some embodiments. The illustrated multi-layered electrode may of course be employed in a bitcell in absence of a multi-layered barrier, and vice versa. As shown in FIG. 3B, electrode 210 incorporates an electrode bulk material 206 and an electrode barrier material 207. Electrode 230 similarly incorporates an electrode barrier material 231 and electrode bulk material 232. In exemplary embodiments, the electrode bulk materials 206, 232 have the same composition (e.g., copper). In further embodiments, electrode barrier material 231 is of a different composition than electrode barrier material 207, though they may also be of the same composition. In one advantageous embodiment, electrode barrier material 207 has the same composition as a barrier material disposed between a selector and memory oxide of the 1S1R bitcell.

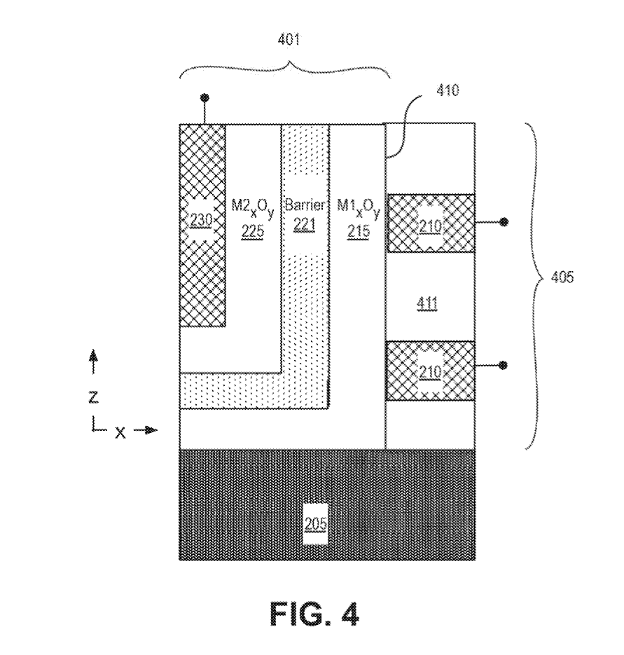

In embodiments, a non-planar 1S1R bitcell includes a barrier layer between memory and selector elements. Although the exemplary embodiments illustrated in FIG. 2A-3B are depicted in a planar bitcell context, it is noted the same thin film stacks may be readily implemented into various non-planar architectures. FIG. 4, for example, is a cross-sectional view illustrating a non-planar thin film 1S1R bitcell 401 incorporating a conductive oxide barrier 221 between a selector dielectric material 225 and memory oxide material 215, in accordance with a non-planar embodiment. Each of these thin films has been deposited on a topographic feature sidewall 410 so that the direction of current flow through bitcell 401 is substantially planar with substrate 205. To further increase bitcell density, a stack of electrodes 405 may form sidewall 410 with a dielectric 411 disposed between each electrode 210.

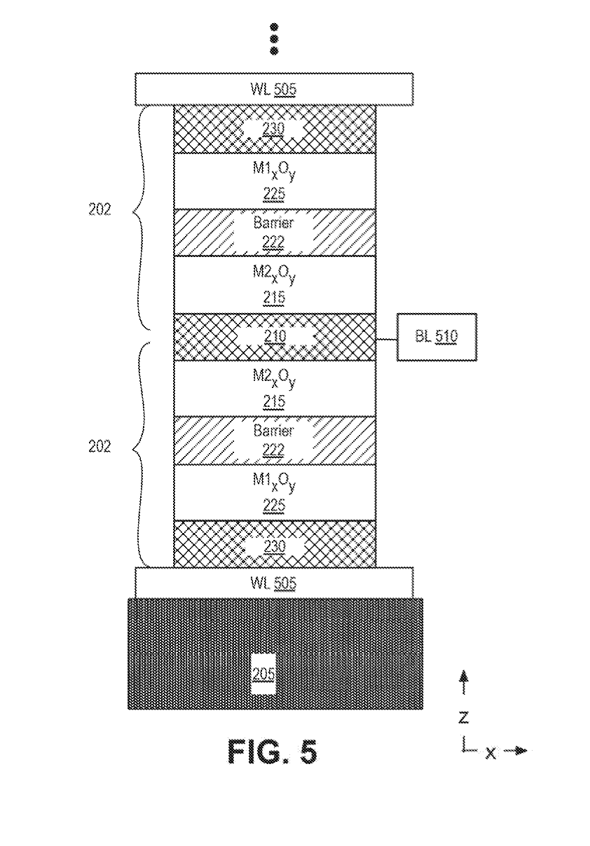

FIG. 5 is a cross-sectional view illustrating stacked thin film 1S1R bitcells, in accordance with embodiments. Resistive memory array density may be increased by (vertically) stacking the 1S1R bitcell. In the exemplary embodiment illustrated in FIG. 5, a first 1S1R bitcell 202 is stacked back-to-back with a second 1S1R bitcell 202 between two wordlines 505. A bitline 510 couples to electrode 210, common to both bitcells. Each bitcell 202, includes a metal nitride, carbide, or carbonitride barrier material 222, as described above.

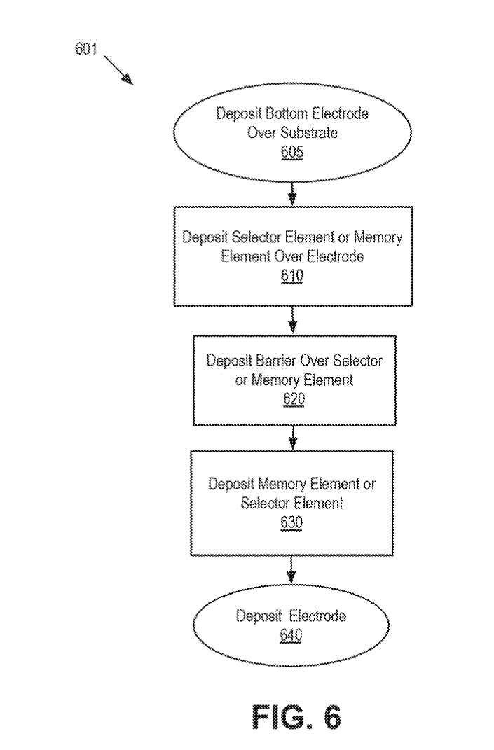

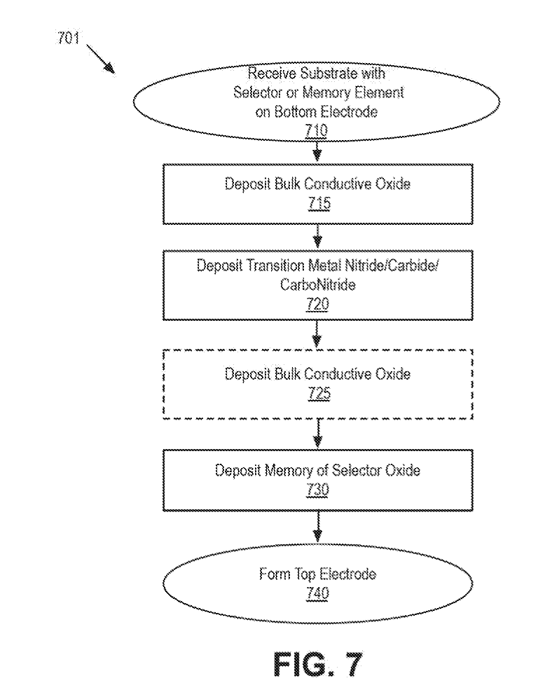

The bitcell architectures described above may be fabricated by many techniques. FIG. 6 is a flow diagram illustrating a method 601 of forming a thin film 1S1R bitcell incorporating a barrier between a selector oxide material and memory oxide material, in accordance with embodiments. Method 601 may be employed to form bitcell 201 illustrated in FIG. 3B, for example. FIG. 7 is a flow diagram illustrating a method 701 of forming a thin film 1S1R bitcell incorporating a multi-layered barrier between a selector oxide material and memory oxide material, in accordance with embodiments. Method 701 may be employed to form bitcell 205 illustrated in FIG. 3B, for example.

Referring first to FIG. 6, method 601 begins at operation 605 with depositing a first (bottom) electrode material over a substrate. Any deposition process know in the art to be suitable for the particular electrode composition may be utilized at operation 605, such as, but not limited to, physical vapor deposition (PVD), chemical vapor deposition (CVD), atomic layer deposition (ALD), electrolytic and electroless plating, and spin-on techniques.

At operation 610 a thin film memory element or a thin film selector element is deposited over the first electrode material. Any deposition process know in the art to be suitable for the particular memory/selector element may be utilized at operation 610, such as, but not limited to, PVD, CVD, and ALD techniques. In one exemplary planar embodiment, reactive PVD is employed at operation 610. In one exemplary non-planar embodiment, ALD is employed at operation 610.

At operation 620 a thin film barrier is deposited over the element deposited at operation 610 (e.g., memory element or a thin film selector element). Any deposition process know in the art to be suitable for the particular barrier layer may be utilized at operation 610, such as, but not limited to, PVD, CVD and ALD techniques. In one exemplary planar embodiment, reactive PVD is employed at operation 620. In one exemplary non-planar embodiment, ALD is employed at operation 620.

Method 601 continues with operation 630 where the other of the memory element and the selector element (i.e., the element not deposited at operation 610) is deposited over the barrier material deposited at operation 620. Any deposition process know in the art to be suitable for the particular memory/selector element may be utilized at operation 630 such as, but not limited to, PVD, CVD, and ALD techniques. In one exemplary planar embodiment, reactive PVD is employed at operation 630. In one exemplary non-planar embodiment, ALD is employed at operation 630. Method 601 completes with depositing a second electrode material over the memory/selector element deposited at operation 630 using any conventional technique. For stacked bitcell embodiments, method 601 may be repeated, with the various operations performed in the same, or opposite, order.

Referring to FIG. 7 for multi-layered barrier embodiments, method 701 begins with receiving a substrate with the selector/memory element disposed on an electrode at operation 710. At operation 715, a bulk conductive oxide is deposited. Any deposition process know in the art to be suitable for the particular conductive oxide barrier material chosen may be utilized at operation 715 such as, but not limited to, PVD, CVD, and ALD techniques. In one exemplary planar embodiment, reactive PVD is employed at operation 715. In one exemplary non-planar embodiment, ALD is employed at operation 715. At operation 720, a barrier layer comprising a nitride, carbide, or carbonitride of a refractory metal is deposited directly on the conductive oxide that was deposited at operation 715. Method 701 continues with a second bulk conductive oxide further deposited at operation 725, which is optional as denoted by dashed line in FIG. 7. The memory/selector oxide material is then deposited at operation 730, and method 701 completed with deposition of a second (top) electrode at operation 740 by any conventional technique.

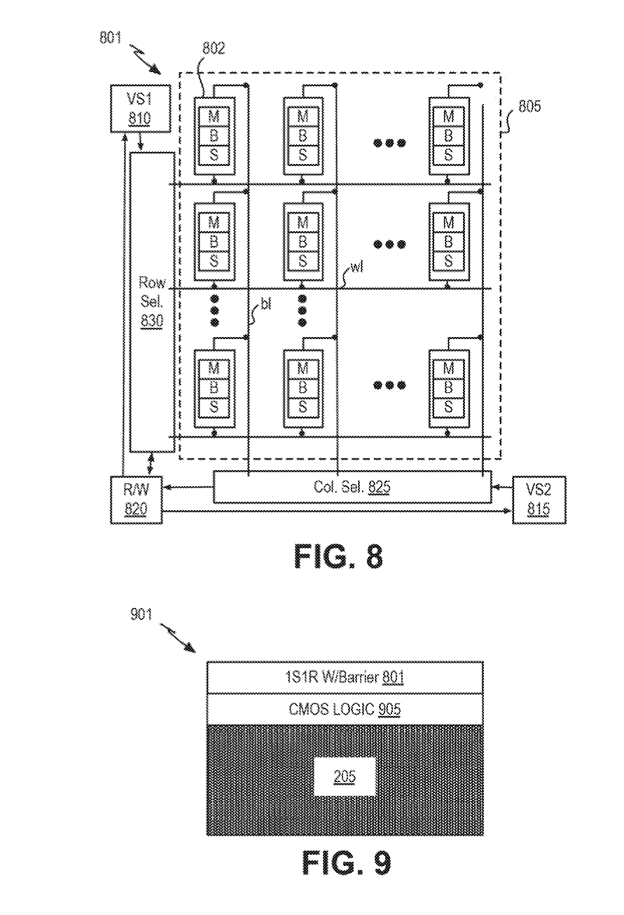

FIG. 8 is a schematic of a NVM 801 including a plurality of thin film 1S1R bitcells 802, each incorporating a barrier B between a selector element S and memory element M, in accordance with embodiments. Each bitcell 802 includes a bidirectional memory element and a selector connected in series with any of the barrier embodiments described elsewhere herein disposed there between. Array 805 is a bidirectional cross point array including any number of bitcells 802. Each column is associated with a bitline driven by a column select circuit in column select circuitry 825. Each row is associated with a wordline driven by a row select circuit in row select circuitry 830. In an operative state, R/W control circuitry 820 receives memory access requests (e.g., from a local processor or communication chip in which the memory is embedded), generates the requisite control signals based on the requests (e.g., read, write 0, or write 1), and controls the row and column select circuitry 825, 830. Voltage supplies 810, 815 are controlled to provide the voltage necessary to bias the array to facilitate the requested action on one or more bitcell 802. Row and column select circuitry 825, 830 applies the supplied voltage across array 805 to access selected bitcell(s). Row select circuitry 825, column select circuitry 830, and R/W control circuitry 820 may be implemented with any known technology. In one exemplary embodiment, the maximum supply voltage that is available from voltage supplies 810, 815 for a write operation is less than 1 volt.

FIG. 9 illustrates a cross-section of e-NVM 901, in accordance with exemplary embedded resistive memory embodiments. As illustrated, e-NMV 901 includes NVM 801 monolithically integrated with CMOS logic 905 over substrate 205. In this exemplary embodiment, NVM 701(including a plurality of thin film 1S1R bitcells, each incorporating one or more barrier material between a selector element and memory element) is disposed over CMOS logic 905, for example as part of a BEOL film stack. CMOS logic 905 may include any metal-oxide-semiconductor transistors known (e.g. MOSFETs), one or more of which is electrically coupled to NVM 701.

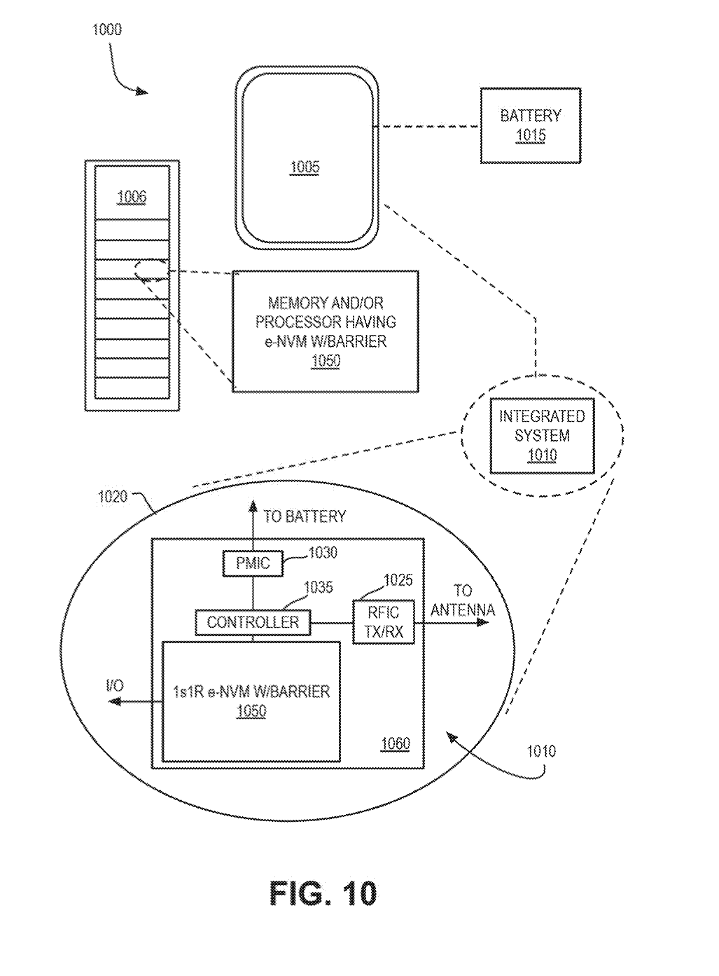

FIG. 10 illustrates a mobile computing platform and a data server machine employing an SoC having e-NVM with 1S1R bitcells incorporating a barrier between selector and memory elements, in accordance with embodiments of the present invention. The server machine 1006 may be any commercial server, for example including any number of high-performance computing platforms disposed within a rack and networked together for electronic data processing, which in the exemplary embodiment includes a packaged monolithic IC 1050. The mobile computing platform 1005 may be any portable device configured for each of electronic data display, electronic data processing, wireless electronic data transmission, or the like. For example, the mobile computing platform 1005 may be any of a tablet, a smart phone, laptop computer, etc., and may include a display screen (e.g., a capacitive, inductive, resistive, or optical touchscreen), a chip-level or package-level integrated system 1010, and a battery 1015.

Whether disposed within the integrated system 1010 illustrated in the expanded view 1020, or as a stand-alone packaged chip within the server machine 1006, packaged monolithic IC 1050 includes a memory chip (e.g., RAM), or a processor chip (e.g., a microprocessor, a multi-core microprocessor, graphics processor, or the like) including at least one NVM with 1S1R bitcells that include a barrier, for example as described elsewhere herein. The monolithic IC 1050 may be further coupled to a board, a substrate, or an interposer 1060 along with, one or more of a power management integrated circuit (PMIC) 1030, RF (wireless) integrated circuit (RFIC) 1025 including a wideband RF (wireless) transmitter and/or receiver (TX/RX) (e.g., including a digital baseband and an analog front end module further comprises a power amplifier on a transmit path and a low noise amplifier on a receive path), and a controller thereof 1035.

Functionally, PMIC 1030 may perform battery power regulation, DC-to-DC conversion, etc., and so has an input coupled to battery 1015 and with an output providing a current supply to other functional modules. As further illustrated, in the exemplary embodiment, RFIC 1025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. In alternative implementations, each of these board-level modules may be integrated onto separate ICs coupled to the package substrate of the monolithic IC 1050 or within a single IC coupled to the package substrate of the monolithic IC 1050.

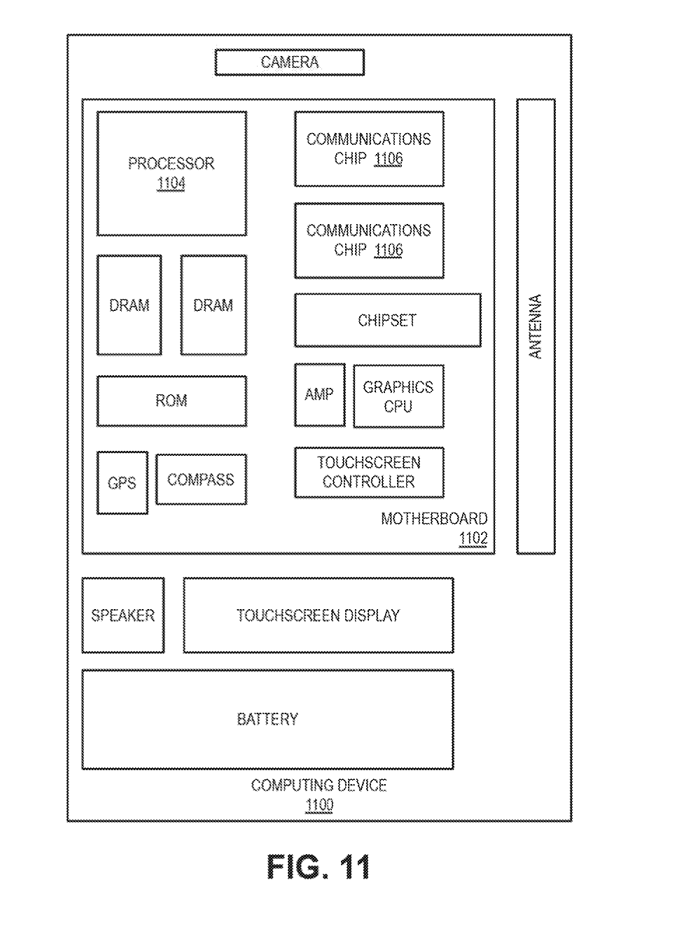

FIG. 11 is a functional block diagram of a computing device 1100, arranged in accordance with at least some implementations of the present disclosure. Computing device 1100 may be found inside platform 1005 or server machine 1006, for example. Device 1100 further includes a motherboard 1102 hosting a number of components, such as, but not limited to, a processor 1104 (e.g., an applications processor), which may further incorporate at least one NVM with 1S1R bitcells that include a barrier, for example as described elsewhere herein. Processor 1104 may be physically and/or electrically coupled to motherboard 1102. In some examples, processor 1104 includes an integrated circuit die packaged within the processor 1104. In general, the term “processor” or “microprocessor” may refer to any device or portion of a device that processes electronic data from registers and/or memory to transform that electronic data into other electronic data that may be further stored in registers and/or memory.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

One or more first embodiments, a resistive memory cell includes a substrate, a first and second electrode material disposed over the substrate, and a thin film memory element and a thin film selector element disposed between the first and second electrode materials. The resistive memory cell further includes an electrically floating conductive thin film barrier disposed between the memory element and selector element.

In furtherance of the first embodiments, the selector element further includes a selector oxide material of a first composition that is to undergo a volatile transition between low and high resistance states at a threshold voltage. The memory element further comprises a memory oxide material of a second composition that is to undergo a non-volatile transition between low and high resistance states at a set/reset voltage. The thin film barrier comprises at least one of a bulk conductive metal oxide layer, or a non-oxide metallic compound layer comprising refractory metal nitride, carbide, or carbonitride.

In furtherance of the embodiment immediately above, the refractory metal nitride, carbide, or carbonitride includes at least one of: TiN, TaN, WN, TiC, TaC, WC, or TaCN.

In furtherance of the embodiment immediately above, the refractory metal nitride, carbide, or carbonitride is at least one of: TiN, TaN, WN, TiC, TaC, WC, or TaCN.

In furtherance of the embodiment above, the barrier is a bulk conductive metal oxide layer including at least one of: RuO₂, CrO₂, WO₂, IrO₂, MoO₂, PtO₂, or RhO₂.

In furtherance of the embodiment above, the barrier is a bulk conductive metal oxide layer is at least one of: RuO₂, CrO₂, WO₂, IrO₂, MoO₂, PtO₂, or RhO₂.

In furtherance of the embodiment above, the barrier is a stack including the non-oxide metallic compound layer, and the bulk conductive oxide layer disposed between the non-oxide metallic compound layer and at least one of the selector oxide material and the memory oxide material.

In furtherance of the embodiment immediately above, the selector oxide material is disposed over the memory oxide material and the barrier is a stack comprising the bulk conductive oxide layer disposed over the memory oxide material and the non-oxide metallic compound layer is disposed over the bulk conductive oxide layer, or the memory oxide material is disposed over the selector oxide material and the barrier is a stack comprising the bulk conductive oxide layer disposed over the selector oxide material and the non-oxide metallic compound layer is disposed over the bulk conductive oxide layer.

In furtherance of the first embodiments, the barrier is a stack comprising the non-oxide metallic compound layer disposed between a first and second bulk conductive metal oxide layer.

In furtherance of the embodiment immediately above, the non-oxide metallic compound layer includes at least one of: TiN, TaN, WN, TiC, TaC, WC, or TaCN. The first and second bulk conductive metal oxide layer includes at least one of: RuO₂, CrO₂, WO₂, IrO₂, MoO₂, PtO₂, or RhO₂.

In furtherance of the embodiment immediately above, the non-oxide metallic compound layer is at least one of: TiN, TaN, WN, TiC, TaC, WC, or TaCN. The first and second bulk conductive metal oxide layer is at least one of: RuO₂, CrO₂, WO₂, IrO₂, MoO₂, PtO₂, or RhO₂.

In furtherance of the first embodiment, at least one of the first and second electrode materials further comprises a stack including a second thin film barrier between a bulk electrode material and the selector or memory element.

In furtherance of the first embodiment, the selector oxide material comprises a transition metal predominantly at a first oxidation state; and the selector oxide material comprises the transition metal predominantly at a second oxidation state, different from the first oxidation state.

In furtherance of the first embodiment, the selector oxide material is at least one of VO₂, Ta₂O₅, NbO₂, Ti₃O₅, Ti₂O₃, LaCoO₃, or SmNiO₃; and the memory oxide material is an anionic-based conductive oxide material selected from the group consisting of an oxide of vanadium (V), an oxide of chromium (Cr), an oxide of niobium (Nb), and an oxide of tantalum, (Ta), an oxide of hafnium (Hf), or is a cationic-based conductive oxide material selected from the group consisting of LiMnO₂, Li₄TiO₁₂, LiNiO₂, LiNbO₃, Li₃N:H, LiTiS₂, Na b-alumina, AgI, RbAg₄I₅, and AgGeAsS₃.

In one or more second embodiment, a system on chip (SoC), includes a resistive memory array including a plurality of resistive memory bitcells, each bitcell further including a first and second electrode material disposed over a substrate, a thin film memory element and a thin film selector element disposed between the first and second electrode materials, and an electrically floating conductive thin film barrier disposed between the memory element and selector element, wherein the first and second electrode materials are further coupled to a wordline and a bitline. The SoC further includes a plurality of MOS transistors disposed over the substrate, one or more of the plurality of transistors electrically coupled to the resistive memory array.

In one or more third embodiment, a method of fabricating a resistive memory cell includes depositing a first electrode material over a substrate. The method further includes depositing one of a thin film memory element and a thin film selector element over the first electrode material. The method further includes depositing a conductive thin film barrier over the memory or selector element. The method further includes depositing the other of the memory element and the selector element over the barrier. The method further includes depositing a second electrode material over the other of the memory element and the selector element.

In furtherance of the embodiment immediately above, depositing the memory element further includes depositing a memory oxide of a first composition that is to undergo a non-volatile transition between low and high resistance states at a set/reset voltage, depositing the selector element further comprises depositing a selector oxide material of a second composition that is to undergo a volatile transition between low and high resistance states at a threshold voltage, and depositing the barrier further comprises depositing a non-oxide metallic compound layer comprising a nitride, carbide, or carbonitride of a refractory metal.

In furtherance of the embodiment immediately above, depositing the non-oxide metallic compound layer further comprises depositing at least one of: TiN, TaN, WN, TiC, TaC, WC, and TaCN.

In furtherance of the third embodiment, depositing the barrier further comprises depositing a bulk conductive oxide over the memory of selector element, and depositing the non-oxide metallic compound layer over the bulk conductive oxide.

In furtherance of the embodiment immediately above, depositing the bulk conductive oxide further comprises depositing at least one of: RuO₂, CrO₂, WO₂, IrO₂, MoO₂, PtO₂, or RhO₂.

In furtherance of the embodiment immediately above, depositing the barrier further comprises depositing a second bulk conductive oxide layer over the non-oxide metallic compound layer.

In furtherance of the third embodiment, depositing at least one of the memory oxide material and selector oxide material further comprises depositing the oxide material on a sidewall of a topographic feature with an atomic layer deposition (ALD) process, and depositing the barrier further comprises depositing the non-oxide metallic compound with an ALD process.

In furtherance of the third embodiment, depositing the selector element further comprises depositing VO₂, Ta₂O₅, NbO₂, Ti₃O₅, Ti₂O₃, LaCoO₃, or SmNiO₃.

However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1-20. (canceled)

21. A resistive memory cell, comprising:
a substrate;
a first and second electrode material disposed over the substrate;
a thin film memory element and a thin film selector element disposed between the first and second electrode materials; and
an electrically floating conductive thin film barrier disposed between the memory element and selector element.

22. The resistive memory cell of claim 21, wherein:
the selector element further comprises a selector oxide material of a first composition that is to undergo a volatile transition between low and high resistance states at a threshold voltage;
the memory element further comprises a memory oxide material of a second composition that is to undergo a non-volatile transition between low and high resistance states at a set/reset voltage; and
the thin film barrier comprises at least one of a bulk conductive metal oxide layer, or a non-oxide metallic compound layer comprising refractory metal nitride, carbide, or carbonitride.

23. The resistive memory cell of claim 22, wherein the refractory metal nitride, carbide, or carbonitride includes at least one of: TiN, TaN, WN, TiC, TaC, WC, or TaCN.

24. The resistive memory cell of claim 22, wherein the barrier comprises a bulk conductive metal oxide layer including at least one of: RuO₂, CrO₂, WO₂, IrO₂, MoO₂, PtO₂, or RhO₂.

25. The resistive memory cell of claim 22, wherein the barrier is a stack comprising the non-oxide metallic compound layer, and the bulk conductive oxide layer disposed between the non-oxide metallic compound layer and at least one of the selector oxide material and the memory oxide material.

26. The resistive memory cell of claim 25, wherein:
the selector oxide material is disposed over the memory oxide material and the barrier is a stack comprising the bulk conductive oxide layer disposed over the memory oxide material and the non-oxide metallic compound layer is disposed over the bulk conductive oxide layer, or
the memory oxide material is disposed over the selector oxide material and the barrier is a stack comprising the bulk conductive oxide layer disposed over the selector oxide material and the non-oxide metallic compound layer is disposed over the bulk conductive oxide layer.

27. The resistive memory cell of claim 22, wherein the barrier is a stack comprising the non-oxide metallic compound layer disposed between a first and second bulk conductive metal oxide layer.

28. The resistive memory cell of claim 27, wherein:
the non-oxide metallic compound layer comprises at least one of: TiN, TaN, WN, TiC, TaC, WC, or TaCN;
the first and second bulk conductive metal oxide layer comprises at least one of: RuO₂, CrO₂, WO₂, IrO₂, MoO₂, PtO₂, or RhO₂.

29. The resistive memory cell of claim 21, wherein:
at least one of the first and second electrode materials further comprises a stack including a second thin film barrier between a bulk electrode material and the selector or memory element.

30. The resistive memory cell of claim 22, wherein:
the selector oxide material comprises a transition metal predominantly at a first oxidation state; and
the selector oxide material comprises the transition metal predominantly at a second oxidation state, different from the first oxidation state.

31. The resistive memory cell of claim 22, wherein:
the selector oxide material comprises at least one of VO₂, Ta₂O₅, NbO₂, Ti₃O₅, Ti₂O₃, LaCoO₃, or SmNiO₃; and
the memory oxide material comprises:
an anionic-based conductive oxide material selected from the group consisting of an oxide of vanadium, an oxide of chromium, an oxide of niobium, an oxide of tantalum, and an oxide of hafnium (Hf), or
a cationic-based conductive oxide material selected from the group consisting of LiMnO₂, Li₄TiO₁₂, LiNiO₂, LiNbO₃, Li₃N:H, LiTiS₂, Na b-alumina, AgI, RbAg₄I₅, and AgGeAsS₃.

32. A system on chip (SoC), comprising:
a resistive memory array including a plurality of resistive memory bitcells, each bitcell further including:
a first and second electrode material disposed over a substrate; and
a thin film memory element and a thin film selector element disposed between the first and second electrode materials;
an electrically floating conductive thin film barrier disposed between the memory element and selector element, wherein the first and second electrode materials are further coupled to a wordline and a bitline; and
a plurality of MOS transistors disposed over the substrate, one or more of the plurality of transistors electrically coupled to the resistive memory array.

33. A method of fabricating a resistive memory cell, comprising:
depositing a first electrode material over a substrate;
depositing one of a thin film memory element and a thin film selector element over the first electrode material;
depositing a conductive thin film barrier over the memory or selector element;
depositing the other of the memory element and the selector element over the barrier; and
depositing a second electrode material over the other of the memory element and the selector element.

34. The method of claim 23, wherein:
depositing the memory element further comprises depositing a memory oxide of a first composition that is to undergo a non-volatile transition between low and high resistance states at a set/reset voltage;
depositing the selector element further comprises depositing a selector oxide material of a second composition that is to undergo a volatile transition between low and high resistance states at a threshold voltage; and
depositing the barrier further comprises depositing a non-oxide metallic compound layer comprising a nitride, carbide, or carbonitride of a refractory metal.

35. The method of claim 24, wherein depositing the non-oxide metallic compound layer further comprises depositing at least one of: TiN, TaN, WN, TiC, TaC, WC, and TaCN.

36. The method of claim 23, wherein depositing the barrier further comprises depositing a bulk conductive oxide over the memory of selector element, and depositing the non-oxide metallic compound layer over the bulk conductive oxide.

37. The method of claim 26, wherein depositing the bulk conductive oxide further comprises depositing at least one of: RuO₂, CrO₂, WO₂, IrO₂, MoO₂, PtO₂, or RhO₂.

38. The method of claim 26, wherein depositing the barrier further comprises depositing a second bulk conductive oxide layer over the non-oxide metallic compound layer.

39. The method of claim 23, wherein:
depositing at least one of the memory oxide material and selector oxide material further comprises depositing the oxide material on a sidewall of a topographic feature with an atomic layer deposition (ALD) process; and
depositing the barrier further comprises depositing the non-oxide metallic compound with an ALD process.

40. The method of claim 23, wherein depositing the selector element further comprises depositing VO₂, Ta₂O₅, NbO₂, Ti₃O₅, Ti₂O₃, LaCoO₃, or SmNiO₃.
